(19) United States
(12) Patent Application Publication
(10) Pub. No.: US 2026/0338831 A1
(43) Pub. Date: Oct. 29, 2026

(54) CANTILEVER-TYPE PROBE FOR PROBE CARD

(71) Applicant: JAPAN ELECTRONIC MATERIALS CORPORATION, Amagasaki-shi, Hyogo (JP)

(72) Inventor: Shohei TAJIMA, Amagasaki-shi, Hyogo (JP)

(73) Assignee: JAPAN ELECTRONIC MATERIALS CORPORATION, Amagasaki-shi, Hyogo (JP)

(21) Appl. No.: 19/113,819

(22) PCT Filed: Sep. 21, 2022
(86) PCT No.: PCT/JP2022/035188

§ 371 Date: Mar. 20, 2025

(51) Int. Cl. G01R 1/067; G01R 1/073

(52) U.S. Cl. CPC G01R 1/06727; G01R 1/07342

(57) ABSTRACT

This cantilever-type probe for a probe card includes a base part, a needle tip part, and a beam part between the base part and the needle tip part. The beam part includes, in the longitudinal direction thereof, a plurality of stress distribution sections where greater stress concentration occurs than in other portions of the beam part.

### TECHNICAL FIELD

The present disclosure relates to a cantilever-type probe for a probe card.

### BACKGROUND ART

A probe card is an electrical connection device used for supplying power, inputting and outputting signals, and grounding by bringing probes into contact with electrode pads of semiconductor devices, in order to perform operational testing of individual semiconductor devices formed on a wafer.

Probes are provided on the surface of the probe card and are configured such that their tips are pressed against the electrode pads of semiconductor devices with a predetermined pressing force.

To increase the number of semiconductor devices formed on a wafer, it is necessary to reduce the size of the semiconductor devices. Accordingly, the electrode pads of semiconductor devices are designed to be smaller, and the distance (pitch) between electrode pads is also reduced. Therefore, in accordance with the miniaturization of semiconductor devices, it is necessary to make the probes finer. However, when the probes are made finer, there is a problem that the mechanical strength of the probes decreases.

Thus, in order to ensure good electrical and mechanical contact with the electrode pads of semiconductor devices, for example, Patent Document 1 proposes a structure in which a multilayer metal sheet is used for the probe.

### CITATION LIST

### Patent Document

Patent Document 1: Japanese Laid-Open Patent Publication No. 2018-501490

### SUMMARY OF THE INVENTION

### Problem to be Solved by the Invention

The probe disclosed in Patent Document 1 includes at least one multilayer structure that comprises a core and a first inner coating layer laminated thereon, and a contact probe that has an outer coating layer, which is made of a material having higher hardness than the core and completely covers the multilayer structure.

As disclosed in Patent Document 1, to achieve good electrical and mechanical contact, it is preferable to laminate multiple layers of different materials. However, there is a limit to meeting the demand for reducing the thickness of the cross-section of the probe, and further breakthroughs have been required.

In the inspection process of semiconductor devices using the above probe card, to ensure contact with the electrode pads of semiconductor devices, after the probes make contact with the electrode pads, the probe card is further brought closer to the semiconductor wafer (overdrive), thereby pressing the probes against the electrode pads of the semiconductor devices.

Therefore, the probes are required to have strength that prevents mechanical destruction even when a contact pressure exceeding a certain threshold is applied. To prevent destruction, it is necessary to prevent localized stress concentration in the probes. To achieve this, probes with as smooth and scratch-free surfaces as possible have been required.

However, there is a limit to how smooth a metal surface can be made, and the thinner the cross-sectional thickness of the probe, the more easily it deforms under external force (i.e., the lower its mechanical strength).

The present disclosure provides technology to solve the above problems and aims to provide a cantilever-type probe for a probe card that maintains adequate needle pressure when contacting the electrode pads of semiconductor devices, while also having sufficient strength to withstand applied contact pressure beyond a certain threshold without breaking.

That is, the cantilever-type probe for a probe card disclosed in the present application is not designed to eliminate stress concentration but rather to intentionally distribute the positions where stress concentration occurs, thereby providing a cantilever-type probe for a probe card with high mechanical strength that can withstand high stress.

### Means to Solve the Problem

A cantilever-type probe for a probe card according to the present disclosure includes: a base part; a needle tip part; and a beam part arranged between the base part and the needle tip part. The beam part includes a plurality of stress distribution sections in a longitudinal direction, the stress distribution sections being regions where greater stress concentration occurs than in other portions of the beam part.

### Effect of the Invention

According to the cantilever-type probe for a probe card disclosed in the present application, even if the thickness of the probe is reduced, it is possible to provide a cantilever-type probe for a probe card with high mechanical strength by distributing the positions where stress concentration occurs.

### BRIEF DESCRIPTION OF THE DRAWINGS

FIG. 1 is a perspective view of a cantilever-type probe for a probe card according to Embodiment 1.

FIG. 2A is a plan view of the portion enclosed by a dashed line in FIG. 1.

FIG. 2B is a cross-sectional view taken along line A-A in FIG. 2A.

FIG. 3A is a plane view showing a state in which a sacrificial layer is arranged to manufacture the portion enclosed by a dashed line in FIG. 1.

FIG. 3B is a diagram illustrating a state in which the B-B line part in FIG. 3A is under manufacturing.

FIG. 4 is a cross-sectional view of a modified example of the probe according to Embodiment 2.

FIG. 5A is a plan view of a modified example of the probe according to Embodiment 2.

FIG. 5B is a cross-sectional view taken along line C-C in FIG. 5A.

FIG. 6A is a plan view of a modified example of the probe according to Embodiment 2.

FIG. 6B is a cross-sectional view taken along line D-D in FIG. 6A.

FIG. 7A is a plan view of a modified example of the probe according to Embodiment 2.

FIG. 7B is a cross-sectional view taken along line E-E in FIG. 7A.

FIG. 8A is a cross-sectional view of a modified example of the probe according to Embodiment 3.

FIG. 8B is a cross-sectional view taken along line F-F in FIG. 8A.

FIG. 9A is a plan view of a modified example of the probe according to Embodiment 4.

FIG. 9B is a cross-sectional view taken along line G-G in FIG. 9A.

### DESCRIPTION OF EMBODIMENTS

### Embodiment 1

Hereinafter, a cantilever-type probe for a probe card according to Embodiment 1 will be described with reference to the drawings.

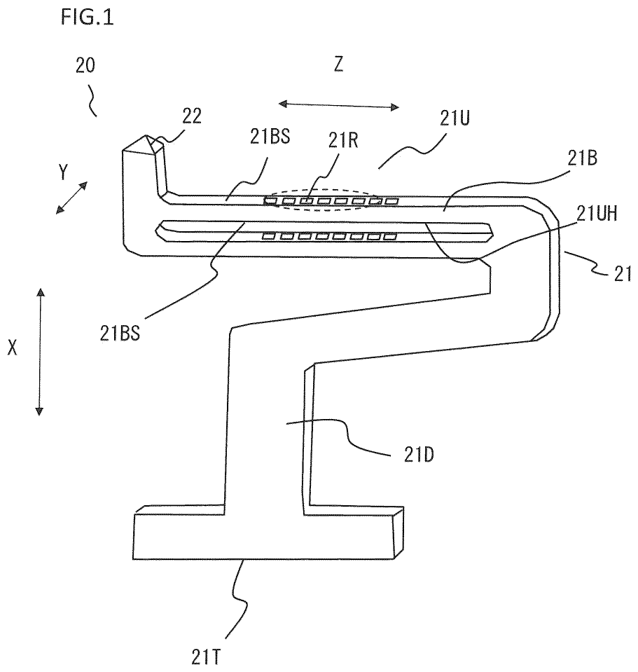

FIG. 1 is a perspective view of a cantilever-type probe for a probe card 20 (hereinafter simply referred to as “probe 20”).

In the present specification, the upper side of FIG. 1 is referred to as “upper,” and the lower side is referred to as “lower.” The direction in which the probe 20 undergoes buckling (elastic deformation) during overdrive is referred to as the buckling direction X, the direction perpendicular to the buckling direction X and corresponding to the thickness direction of the probe 20 is referred to as the thickness direction Y, and the longitudinal direction of the beam part 21B of the probe 20 is referred to as the longitudinal direction Z.

The probe 20 is a component used in a probe card (not illustrated). A probe card is a device used to inspect the electrical characteristics of an electronic circuit formed on a semiconductor wafer. The characteristic inspection of the electronic circuit is performed by bringing the semiconductor wafer close to the probe card so that the needle tip part 22 of the probe 20 contacts the electrode of the electronic circuit, thereby establishing conduction between a tester device and the tester connection electrode on the wiring board of the probe card via the probe 20.

The probe 20 is a cantilever-type probe configured such that the beam part 21B is arranged substantially horizontally with respect to the inspection target (the electronic circuit formed on the semiconductor wafer). FIG. 1 illustrates an example in which the probe 20 includes two beam parts 21B, but the beam part 21B may consist of a single beam or three or more beams.

The probe 20 comprises a thin plate-shaped body part 21 and a needle tip part 22 protruding upward from an upper end of the body part. The body part 21 comprises: a terminal portion 21T connected to a wiring land of a wiring board (not illustrated); a base part 21D extending upward from the terminal portion 21T; and an elastic deformation portion 21U arranged between the base part 21D and the needle tip part 22 on the inspection target side.

The elastic deformation portion 21U extends in the longitudinal direction Z and has two elongated holes 21UH that penetrate in the thickness direction Y. The elongated holes 21UH divide the elastic deformation portion 21U into two beam parts 21B.

During overdrive, a compressive force in the vertical direction of FIG. 1 is applied to the probe 20, causing the probe 20 to easily buckle in the buckling direction X in response to the reaction force from the inspection target. At this time, stress is generated inside the probe 20. The probe 20 comprises, on the surface 21BS of the beam part 21B perpendicular to the buckling direction X, a plurality of recesses 21R that function as stress distribution sections to disperse the internal stress generated during overdrive. The plurality of recesses 21R are arranged along the longitudinal direction Z of the beam part 21B.

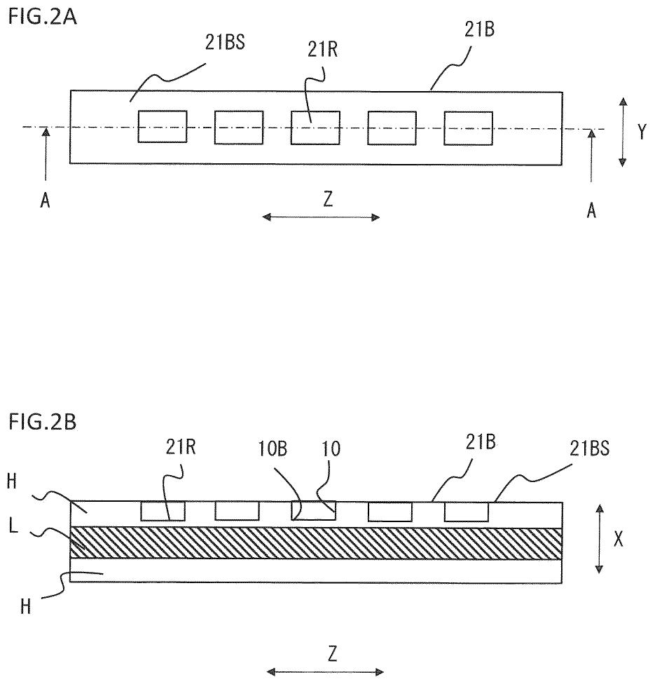

FIG. 2A is a plan view of the portion enclosed by a dashed line in FIG. 1, showing the beam part 21B as viewed in the buckling direction X.

FIG. 2B is a cross-sectional view taken along line A-A in FIG. 2A.

The probe 20 has conductivity and is composed of two types of metals with different resistivities. One is an inner metal (first metal) that constitutes a low-resistance portion L, made of metal with low resistivity such as copper (Cu), gold (Au), or silver (Ag). The low-resistance portion L functions to enhance electrical conductivity and improve current-carrying performance. The other is an outer metal (second metal) that constitutes a high-resistance portion H, made of metal with higher resistivity than the low-resistance portion L, such as a palladium-cobalt (PdCo) alloy. Although the high-resistance portion H has lower conductivity, it has high mechanical strength and spring properties. The high-resistance portion H functions to maintain the mechanical strength of the probe 20.

As shown in FIG. 2A, on the surface 21BS (upper surface) of the beam part 21B perpendicular to the buckling direction X, a plurality of rectangular prism-shaped recesses 21R are arranged at intervals along the longitudinal direction Z. These recesses 21R are formed in the high-resistance portion H. When comparing a probe A without recesses 21R and the probe 20 with recesses 21R, in terms of the relationship between overdrive amount and needle pressure, the probe 20 with recesses 21R exhibits lower needle pressure.

Furthermore, an analysis was conducted to determine the effects of recesses 21R. A finite element method (FEM) analysis was performed to determine the maximum stress in probe A (without recesses 21R) and probe 20 (with rectangular prism-shaped recesses 21R). The results showed that, when external force is applied, stress is concentrated at each vertex 10B of the recesses 21R, as well as along each ridge 10 formed by two adjacent surfaces of the recesses 21R shown in FIG. 2B.

Accordingly, by arranging the rectangular prism-shaped recesses 21R evenly along the longitudinal direction Z of the beam part 21B of the probe 20, the internal stress generated during overdrive can be evenly distributed at each vertex 10B and ridge 10 of the recesses 21R.

In FIG. 2B, an example is shown where the recesses 21R do not penetrate the high-resistance portion H (in other words, the high-resistance portion H remains between the recesses 21R and the low-resistance portion L). However, the recesses 21R may be formed such that to penetrate the high-resistance portion H and reach the low-resistance portion L (in other words, the low-resistance portion L is exposed in the recesses 21R). Compared to cases where the recesses 21R do not penetrate the high-resistance portion H, extending the ridges 10 of the recesses 21R can further enhance stress concentration at the recesses 21R.

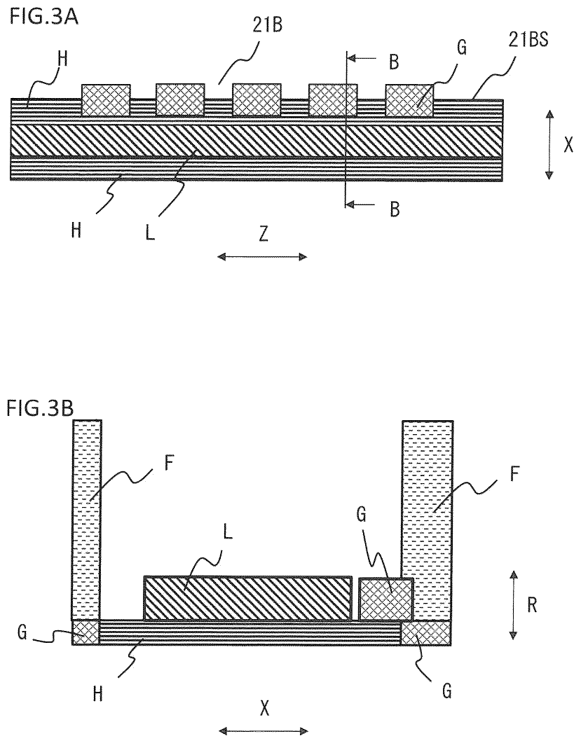

FIG. 3A is a plane view showing a state in which a sacrificial layer G is arranged to manufacture the portion enclosed by a dashed line in FIG. 1 viewed from the stacking direction R. In FIG. 3A, photoresist F is not shown.

FIG. 3B is a diagram illustrating a state in which the B-B line part in FIG. 3A is under manufacturing. Arrow R shows the stacking direction during manufacturing. For explanation purposes, the scales of FIG. 3A and FIG. 3B are different.

The probe 20 is manufactured using MEMS (Micro Electro Mechanical Systems) technology. MEMS technology is a technique for creating fine three-dimensional structures using photolithography technology and sacrificial layer etching technology.

Photolithography technology is a fine patterning technique that uses a photoresist F, commonly used in semiconductor manufacturing processes. Sacrificial layer etching technology involves forming a sacrificial layer G as a lower layer, then forming structural layers on top of it, and subsequently removing only the sacrificial layer G by etching to create a three-dimensional structure.

For forming the high-resistance portion H and low-resistance portion L, well-known plating technology can be utilized. For example, by immersing a substrate serving as a cathode and a metal piece serving as an anode into electrolyte solution, and applying voltage between the electrodes, metal ions in the electrolyte solution can be deposited onto the surface of the substrate.

This process is called electroplating, which is a wet process that involves immersing the substrate in an electrolyte solution. After the plating process, a drying process is performed, followed by a polishing process to refine the needle tip part 22.

Specifically, as shown in FIG. 3B, first, a bottom layer of a high-resistance portion H is formed between sacrificial layers G. Next, a low-resistance portion L is formed on the high-resistance portion H, and then sacrificial layers G are formed in regions corresponding to recesses 21R. Subsequently, the remaining part of the high-resistance portion H is formed, and the photoresist F and the sacrificial layers G are removed. Through these steps, the probe 20 is obtained in which recesses 21R are formed on a surface 21BS of the beam part 21B perpendicular to the buckling direction X. Note that in the present embodiment, an example is described in which two types of metals, the high-resistance portion H and the low-resistance portion L, are used, but the probe may also be manufactured using a single type of metal. Additionally, while an example is described in which the elastic deformation portion 21U is divided into multiple beam parts 21B, the elastic deformation portion 21U may also be configured without division.

According to the cantilever-type probe for a probe card of Embodiment 1, the stress generated inside the probe 20 during inspection can be evenly distributed at each vertex 10B and ridge 10 of the recesses 21R. As a result, both mechanical strength maintenance and needle pressure reduction can be achieved.

### Embodiment 2

Hereinafter, a cantilever-type probe for a probe card according to Embodiment 2 will be described, focusing on differences from Embodiment 1.

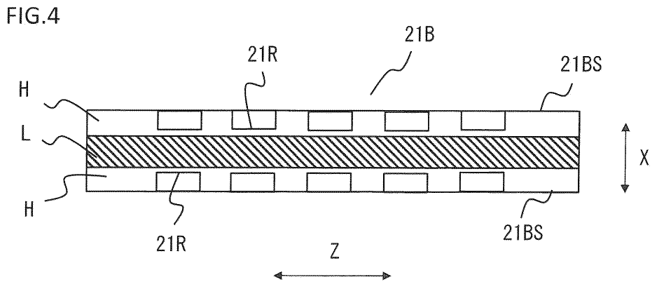

FIG. 4 is a cross-sectional view of a modified example of the probe 20.

In Embodiment 1, an example was described in which recesses 21R were provided only on one surface (upper surface) of the beam part 21B perpendicular to the buckling direction X. However, the recesses 21R may also be provided only on the other surface (lower surface) 21BS of the beam part 21B, or, as shown in FIG. 4, they may be provided on both surfaces.

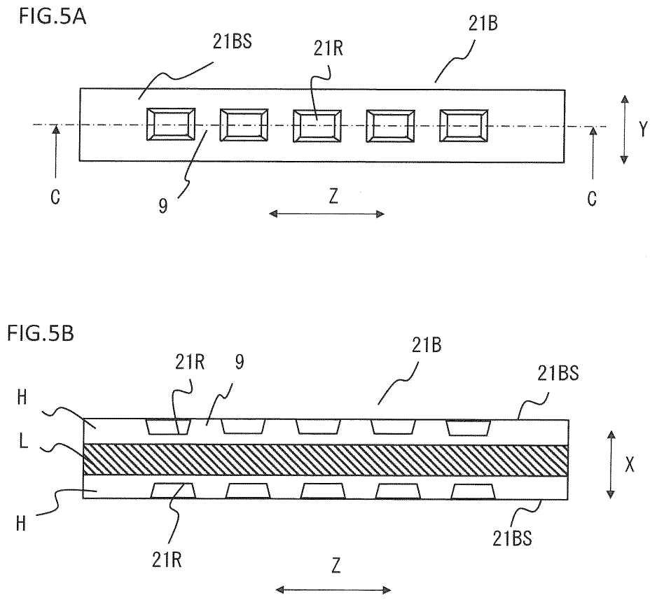

FIG. 5A is a plan view of a modified example of the probe 20.

FIG. 5B is a cross-sectional view taken along line C-C in FIG. 5A.

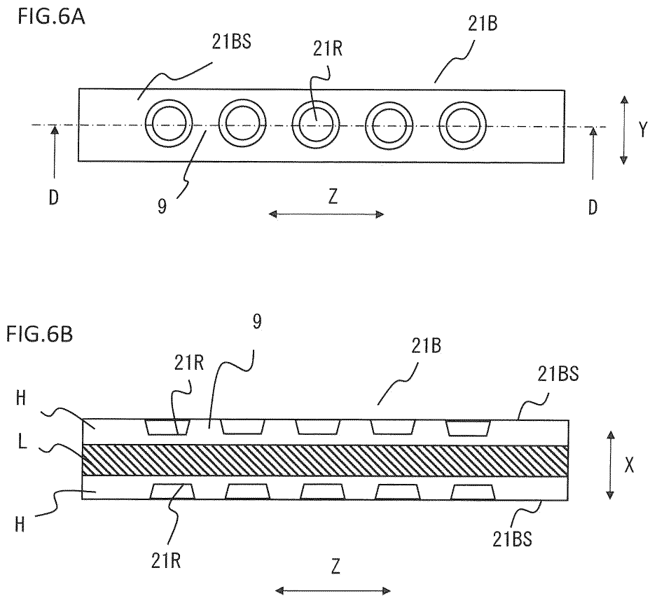

FIG. 6A is a plan view of a modified example of the probe 20.

FIG. 6B is a cross-sectional view taken along line D-D in FIG. 6A. As shown in FIGS. 5A and 5B, the recesses 21R may have a truncated square pyramid shape, or as shown in FIGS. 6A and 6B, they may have a truncated conical shape.

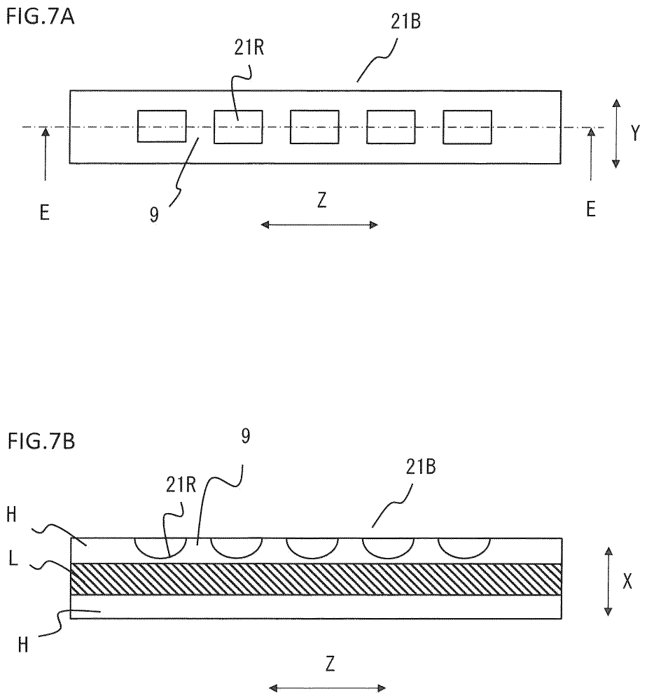

FIG. 7A is a plan view of a modified example of the probe 20.

FIG. 7B is a cross-sectional view taken along line E-E in FIG. 7A.

Furthermore, as shown in FIGS. 7A and 7B, the recesses 21R may have a cylindrical shape cut in the axial direction. When a large number of recesses 21R are arranged, the spacing between adjacent recesses 21R decreases, which may lead to a reduction in the strength of the partition walls 9 between the recesses 21R. Therefore, by inclining the side surfaces of the recesses 21R, the strength of the partition walls 9 between adjacent recesses 21R can be ensured.

According to the cantilever-type probe for a probe card of Embodiment 2, even when a large number of recesses 21R are provided, the strength of the partition walls 9 between adjacent recesses 21R can be maintained.

### Embodiment 3

Hereinafter, a cantilever-type probe for a probe card according to Embodiment 3 will be described, focusing on differences from Embodiment 1.

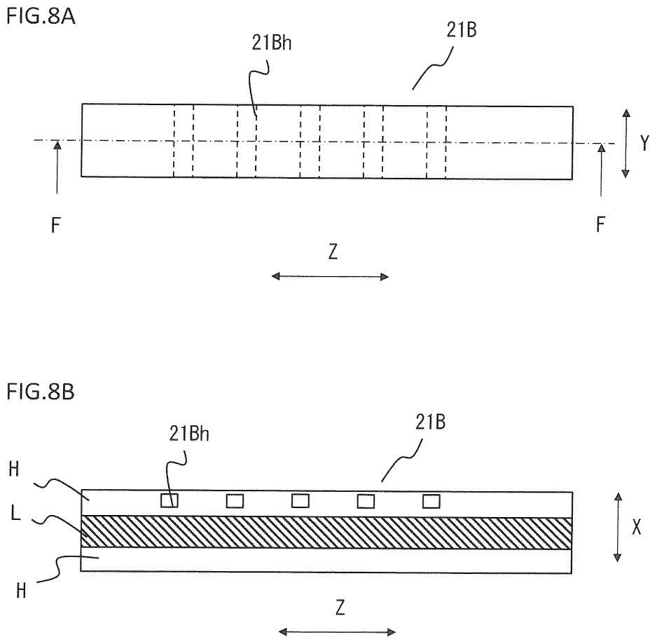

FIG. 8A is a cross-sectional view of a modified example of the probe 20.

FIG. 8B is a cross-sectional view taken along line F-F in FIG. 8A.

In Embodiments 1 and 2, examples were described in which recesses 21R were provided on the surface 21BS of the beam part 21B perpendicular to the buckling direction X.

However, in Embodiment 3, a through-hole 21Bh penetrating the beam part 21B in the thickness direction Y may also be provided instead of the recesses 21R.

According to the cantilever-type probe for a probe card of Embodiment 3, the same effects as Embodiment 1 can be achieved.

### Embodiment 4

Hereinafter, a cantilever-type probe for a probe card according to Embodiment 4 will be described, focusing on differences from Embodiment 1.

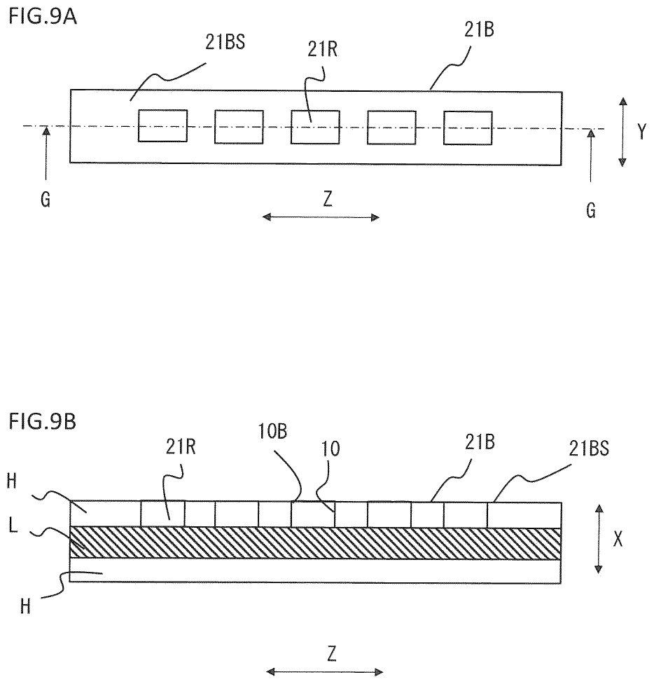

FIG. 9A is a plan view of a modified example of the probe 20.

FIG. 9B is a cross-sectional view taken along line G-G in FIG. 9A.

As shown in FIGS. 9A and 9B, the recesses 21R may be configured to penetrate the high-resistance portion H, being exposed the low-resistance portion L in the recesses 21R. In this case, compared to Embodiments 1 to 3, the number of manufacturing steps can be reduced, offering an advantage in the production process.

Although the disclosure is described above in terms of various exemplary embodiments and implementations, it should be understood that the various features, aspects, and functionality described in one or more of the individual embodiments are not limited in their applicability to the particular embodiment with which they are described, but they can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

20 probe
21 body part
22 needle tip part
21B beam part
21Bh through-hole
21BS surface
21D base part
21U elastic deformation portion
9 partition wall
21R recess
21UH elongated hole
21T terminal portion
10 ridge
10B vertex
F photoresist
G sacrificial layer
H high-resistance portion
L low-resistance portion
X buckling direction
Y thickness direction
Z longitudinal direction

1. A cantilever-type probe for a probe card, comprising:
a base part;
a needle tip part; and
a beam part between the base part and the needle tip part, wherein
the beam part includes, on at least one surface of the beam part perpendicular to a bucking direction thereof, a plurality of stress distribution sections where greater stress concentration occurs than in other portions of the beam part.

2. The cantilever-type probe for a probe card according to claim 1, wherein
the stress distribution sections are recesses provided on at least one surface of the beam part in a buckling direction thereof.

3. The cantilever-type probe for a probe card according to claim 1, wherein
the stress distribution sections are through-holes penetrating the beam part in a thickness direction thereof.

4. The cantilever-type probe for a probe card according to claim 1, wherein
the beam part comprising:
a low-resistance portion made of metal layer having low electrical resistance, and
a high-resistance portion made of metal layer having higher electrical resistance than the low-resistance portion and having spring properties, wherein
the stress distribution sections are formed in the high-resistance portion.

5. (canceled)

6. The cantilever-type probe for a probe card according to claim 2, wherein the beam part comprising:
a low-resistance portion made of metal layer having low electrical resistance, and
a high-resistance portion made of metal layer having higher electrical resistance
than the low-resistance portion and having spring properties, wherein
the stress distribution sections are formed in the high-resistance portion.

7. The cantilever-type probe for a probe card according to claim 3, wherein the beam part comprising:
a low-resistance portion made of metal layer having low electrical resistance, and
a high-resistance portion made of metal layer having higher electrical resistance
than the low-resistance portion and having spring properties, wherein
the stress distribution sections are formed in the high-resistance portion.

8. The cantilever-type probe for a probe card according to claim 4, wherein
the beam part comprises a stacked structure of the low-resistance portion and the high-resistance portion, and
the stress distribution sections are recesses provided in the high-resistance portion, wherein
the low-resistance portion, is exposed in the recesses.

9. The cantilever-type probe for a probe card according to claim 6, wherein
the beam part comprises a stacked structure of the low-resistance portion and the high-resistance portion, and
the stress distribution sections are recesses provided in the high-resistance portion, wherein
the low-resistance portion, is exposed in the recesses.

10. The cantilever-type probe for a probe card according to claim 7, wherein
the beam part comprises a stacked structure of the low-resistance portion and the high-resistance portion, and
the stress distribution sections are recesses provided in the high-resistance portion, wherein
the low-resistance portion, is exposed in the recesses.
